(19) United States
(12) Patent Application Publication
(10) Pub. No.: US 2018/0174802 A1
(43) Pub. Date: Jun. 21, 2018

(54) DIELECTRIC WINDOW, PLASMA SYSTEM THEREWITH, METHOD OF FABRICATING DIELECTRIC WINDOW AND METHOD OF MANUFACTURING SEMICONDUCTOR DEVICE USING THE PLASMA SYSTEM

(71) Applicant: Samsung Electronics Co., Ltd., Suwon-si (KR)

(72) Inventors: Seungkyu LIM, Seoul (KR); DOUGYONG SUNG, Seoul (KR); Myoung Soo PARK, Seongnam-si (KR); Jaehoon KIM, Seoul (KR); Eunyoung LEE, Hwaseong-si (KR); Seiwon CHUNG, Seoul (KR); YOSHIHISA HIRANO, Suwon-si (KR)

(21) Appl. No.: 15/804,304

(22) Filed: Nov. 6, 2017

(30) Foreign Application Priority Data
Dec. 21, 2016 (KR) 10-2016-0175877

(51) Int. Cl. H01J 37/32; H01L 21/67

(52) U.S. Cl. CPC H01J 37/32119; H01J 37/32642; H01L 21/67069; H01L 21/6831; H01J 37/32183; H01J 2237/334; H01J 37/3211

(57) ABSTRACT

A dielectric window, a plasma system including the same, a method of fabricating the same, and a method of manufacturing a semiconductor device are provided. The method of manufacturing the semiconductor device may include steps of providing a substrate in a plasma chamber, performing a plasma treatment on a surface of the substrate, and removing the substrate from the plasma chamber, wherein the plasma chamber comprises the dielectric window. The dielectric window may include a dielectric material disk with at least one void, a filler filled in the void to allow the dielectric material disk to have a flat surface, and a passivation layer provided on the filler and the dielectric material disk.

### CROSS-REFERENCE TO RELATED APPLICATIONS

This U.S. non-provisional patent application claims priority under 35 U.S.C. § 119 to Korean Patent Application No. 10-2016-0175877, filed on Dec. 21, 2016, in the Korean Intellectual Property Office, the entire contents of which are hereby incorporated by reference.

### BACKGROUND OF THE INVENTION

The present disclosure relates to a dielectric window, which is configured to reduce the number of particles caused by plasma, a plasma system including the same, a method of fabricating the dielectric window and a method of manufacturing semiconductor devices using the plasma system.

In general, semiconductor devices are manufactured using a plurality of unit processes, such as a thin-film deposition process, a diffusion process, a thermal treatment process, a photolithography process, a polishing process, an etching process, an ion implantation process, and a cleaning process. Here, the etching process is classified into two processes of dry and wet etching processes. The dry etching process is generally performed using a plasma reaction. In this case, a wafer may be heated to a high temperature, and a plasma system may be damaged by plasma.

### SUMMARY

Exemplary embodiments of the inventive concept provide a dielectric window, which is configured to reduce the number of particles, a plasma system including the same, and a method of manufacturing a semiconductor device.

Exemplary embodiments of the inventive concept provide a plasma system including a long-life ring member.

According to exemplary embodiments of the inventive concept, a dielectric window may include a dielectric material disk with at least one void, a filler filled in the void to allow the dielectric material disk to have a flat top surface, and a passivation layer provided on the filler and the dielectric material disk.

According to exemplary embodiments of the inventive concept, a method of fabricating a dielectric window may include treating a dielectric material disk with a void, forming a filler in the void, and forming a passivation layer on the filler and the dielectric material disk.

According to an exemplary embodiment, a method includes steps of providing a substrate in a plasma chamber, performing a plasma treatment on a surface of the substrate, removing the substrate from the plasma chamber, and separating the substrate into chips, wherein the plasma chamber includes a dielectric window, wherein the substrate is disposed below the dielectric window while the plasma treatment is performed, wherein plasma is formed between the dielectric window and the substrate, and wherein the dielectric window includes a dielectric disk, a first insulating layer formed in a pit of a first surface of the dielectric disk, and a second insulating layer formed on the first insulating layer and on the first surface of the dielectric disk.

According to exemplary embodiments of the inventive concept, a plasma system may include a lower housing, an electrostatic chuck provided in the lower housing and used to load a substrate thereon, a ring member provided to enclose the electrostatic chuck and an edge of the substrate on the electrostatic chuck, an upper housing provided on the ring member and the electrostatic chuck to cover the lower housing, and a dielectric window provided between the upper housing and the lower housing. The dielectric window may include a dielectric material disk with at least one void, a filler provided to fill the at least one void and to planarize a top surface of the dielectric material disk, and a passivation layer provided on the filler and the dielectric material disk.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a schematic diagram illustrating a plasma system according to exemplary embodiments of the inventive concept.

FIG. 2 is a cross-sectional view illustrating an example of a ring member of FIG. 1.

FIG. 3 is a perspective view illustrating an example of a focus ring of FIG. 2.

FIG. 4 is a perspective view illustrating an example of a window of FIG. 1.

FIG. 5 is a cross-sectional view taken along line I-I′ of FIG. 4.

FIG. 6 is a flow chart illustrating a method of fabricating a window, according to exemplary embodiments of the inventive concept.

FIGS. 7 to 10 are cross-sectional views illustrating a method of fabricating a window described with reference to FIG. 6.

FIG. 11 is a flow chart illustrating a method of manufacturing a semiconductor device according to exemplary embodiments of the present disclosure.

### DETAILED DESCRIPTION

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the drawings, like numbers refer to like elements throughout. Though the different figures show various features of exemplary embodiments, these figures and their features are not necessarily intended to be mutually exclusive from each other. Rather, certain features depicted and described in a particular figure may also be implemented with embodiment(s) depicted in different figure(s), even if such a combination is not separately illustrated. Referencing such features/figures with different embodiment labels (e.g. “first embodiment”) should not be interpreted as indicating certain features of one embodiment are mutually exclusive of and are not intended to be used with another embodiment.

Unless the context indicates otherwise, the terms first, second, third, etc., are used as labels to distinguish one element, component, region, layer or section from another element, component, region, layer or section (that may or may not be similar). Thus, a first element, component, region, layer or section discussed below in one section of the specification (or claim) may be referred to as a second element, component, region, layer or section in another section of the specification (or another claim).

It will be understood that when an element is referred to as being “connected,” “coupled to” or “on” another element, it can be directly connected/coupled to/on the other element or intervening elements may be present. In contrast, when an element is referred to as being “directly connected” or “directly coupled” to another element, or as “contacting” or “in contact with” another element, there are no intervening elements present.

Spatially relative terms, such as “beneath,” “below,” “lower,” “above,” “upper” and the like, may be used herein for ease of description to describe one element's or feature's positional relationship relative to another element(s) or feature(s) as illustrated in the figures. It will be understood that such spatially relative terms are intended to encompass different orientations of the device in use or operation in addition to the orientation depicted in the figures. Thus, a device depicted and/or described herein to have element A below element B, is still deemed to have element A below element B no matter the orientation of the device in the real world.

Embodiments may be illustrated herein with idealized views (although relative sizes may be exaggerated for clarity). It will be appreciated that actual implementation may vary from these exemplary views depending on manufacturing technologies and/or tolerances. Therefore, descriptions of certain features using terms such as “same,” “equal,” and geometric descriptions such as “planar,” “coplanar,” “cylindrical,” “square,” etc., as used herein when referring to orientation, layout, location, shapes, sizes, amounts, or other measures, encompass acceptable variations from exact identicality, including nearly identical layout, location, shapes, sizes, amounts, or other measures within acceptable variations that may occur, for example, due to manufacturing processes. The term “substantially” may be used herein to emphasize this meaning, unless the context or other statements indicate otherwise.

As used herein, a semiconductor device may refer to any of the various devices and may also refer, for example, to two transistors or a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

Unless otherwise defined, all terms (including technical and scientific terms) used herein have the same meaning as commonly understood by one of ordinary skill consistent with their meaning in the context of the relevant art and/or the present application.

Example embodiments of the inventive concepts will now be described more fully with reference to the accompanying drawings, in which example embodiments are shown.

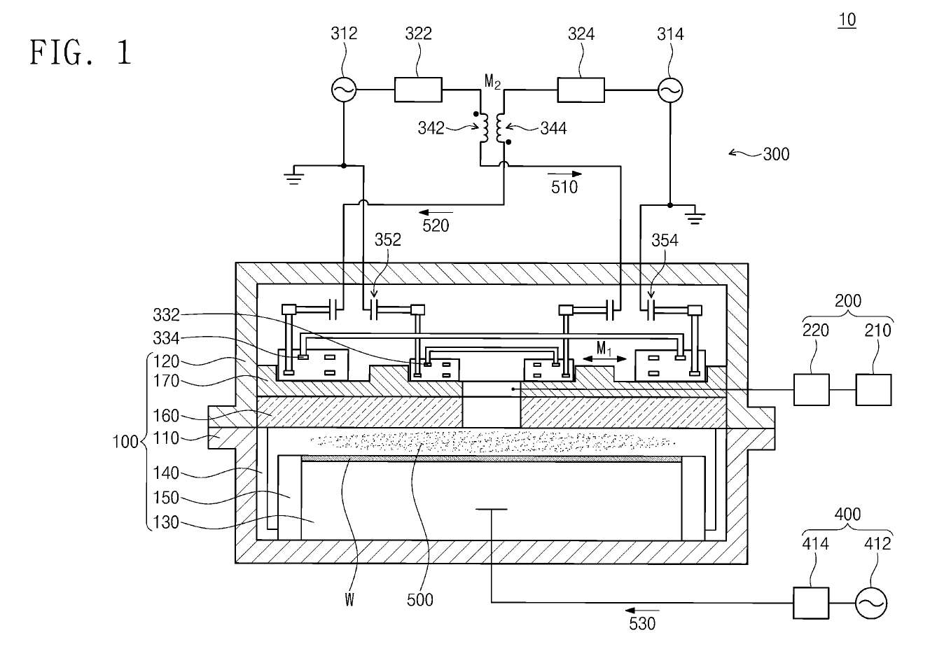

FIG. 1 is a schematic diagram illustrating a plasma system 10 according to exemplary embodiments of the inventive concept.

Referring to FIG. 1, the plasma system 10 may be an inductively coupled plasma (ICP) system. Alternatively, the plasma system 10 may be a capacitively coupled plasma (CCP) system or a microwave plasma system. In exemplary embodiments, the plasma system 10 may include a chamber 100, a gas supply unit 200, an upper radio frequency (RF) power supply unit 300, and a lower RF power supply unit 400. The chamber 100 may be configured to provide an inner space sealed from the outside, and a substrate W may be placed in the inner space of the chamber 100. For example, the chamber 100 may be configured to receive a substrate W in the chamber 100. For example, the substrate W may be processed with plasma in the chamber 100. For example, the chamber 100 may be a plasma chamber in which a plasma process is performed. For example, the substrate W may be a semiconductor substrate. The gas supply unit 200 may be configured to supply gas into the chamber 100. The upper RF power supply unit 300 may be provided over the substrate W and may be used to supply first and second RF powers 510 and 520 in the chamber 100. The first and second RF powers 510 and 520 may be configured to induce plasma 500 in the chamber 100. The lower RF power supply unit 400 may be provided below the substrate W and may be used to supply a third RF power 530 in the chamber 100. The third RF power 530 may be used to concentrate the plasma 500 in a region on the substrate W.

In exemplary embodiments, the chamber 100 may include a lower housing 110, an upper housing 120, an electrostatic chuck 130, a wall liner 140, a ring member 150, a window 160, and an antenna guide 170.

The lower housing 110 may be provided to enclose the electrostatic chuck 130, the wall liner 140, and an edge portion and/or outer wall of the ring member 150. For example, the lower housing 110 may be a bowl-shaped structure.

The upper housing 120 may be provided on the lower housing 110. For example, the upper housing 120 may be provided to cover the lower housing 110. The lower housing 110 and the upper housing 120 may be provided to enclose the electrostatic chuck 130, the wall liner 140, the ring member 150, the window 160, the antenna guide 170, and the substrate W.

The electrostatic chuck 130 may be provided in the lower housing 110. The substrate W may be loaded on the electrostatic chuck 130. The substrate W may be fastened to the electrostatic chuck 130 using electrostatic voltage (not shown).

The wall liner 140 may be provided on an inner sidewall of the lower housing 110. The wall liner 140 may protect the inner sidewall of the lower housing 110. The wall liner 140 may be formed of or include a metallic material (e.g., aluminum).

The ring member 150 may be placed outside the electrostatic chuck 130 and inside the wall liner 140. The ring member 150 may enclose edge portions of the electrostatic chuck 130 and the substrate W. The ring member 150 may protect side surfaces of the electrostatic chuck 130 and the substrate W.

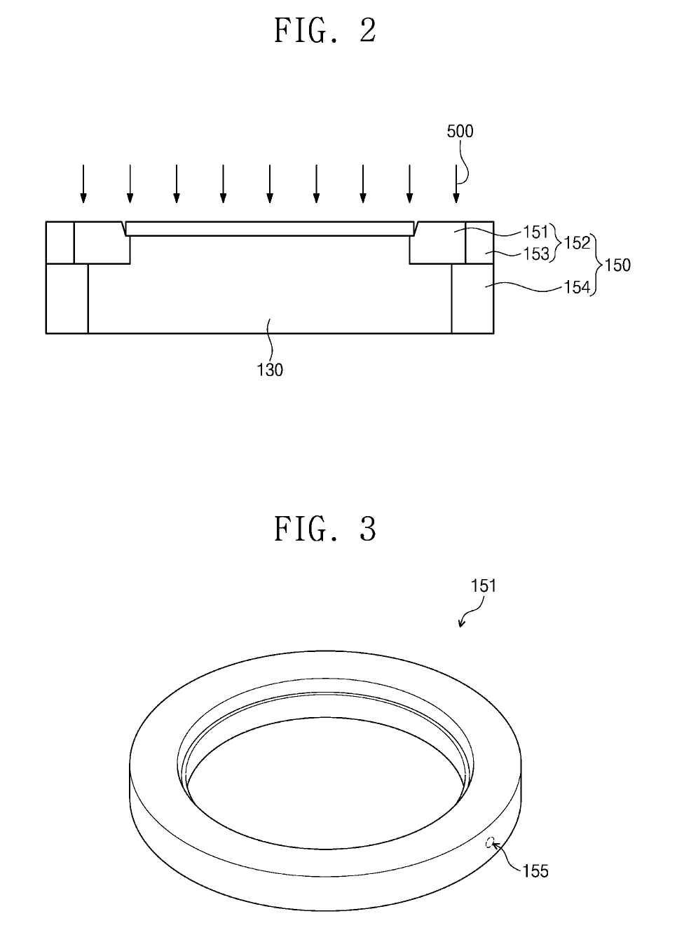

FIG. 2 illustrates an example of the ring member 150 of FIG. 1. FIG. 3 illustrates an example of a focus ring 151 of FIG. 2.

Referring to FIG. 2, the ring member 150 may include an edge ring 152 and a ground ring 154. The edge ring 152 may be provided on the ground ring 154. The edge ring 152 may be provided to surround the substrate W. The ground ring 154 may be provided to surround the electrostatic chuck 130. In exemplary embodiments, the edge ring 152 may include a focus ring 151 and a cover ring 153. For example, the ring member 150 may be a set of rings including the focus ring 151, the cover ring 153 and the ground ring 154. Each ring may have a circular shape.

Referring to FIGS. 2 and 3, the focus ring 151 may be placed inside the cover ring 153. In exemplary embodiments, the focus ring 151 may include quartz that is formed by a plasma fusion method. For example, a plasma fusion method may be a method of forming a fused quartz from a raw material, e.g., crystalline quartz sand, with a plasma spark at a high temperature. The fused quartz may be cool down to form a solid quartz. In exemplary embodiments, the focus ring 151, the cover ring 153 and/or the ground ring 154 may be formed of natural quartz. The focus ring 151 may contain hydroxide (OH), and at least one bubble defect 155 may be formed in the focus ring 151. For example, the focus ring 151 may include an unintended bubble defect 155 or a hole on a surface of the focus ring 151. Since the hydroxide (OH) is easily combined with fluorine constituents in etching gas and the bubble defect 155 is easily etched by the etching gas, the presence of the hydroxide or the bubble defect 155 may cause a reduction of the lifetime of the focus ring 151. The bubble defect 155 may serve as a source of producing particles. For example, because the bubble defect 155 may be easily etched by the etching gas, the area of the bubble defect 155 may easily produce particles. A commonly used focus ring may have a hydroxide (OH) concentration of about 50 ppm or higher and a bubble density of 2 ea/cm³ or higher. For example, in the case where quartz is formed by a flame fused method, it may have a hydroxide concentration of about 230 ppm or higher and a bubble density of 3 ea/cm³ or higher. In the case where quartz is formed by an electric fusion method, it may have a bubble density of 1000 ea/cm³ or higher. For example, 1000 bubbles or more may be formed in a cubic centimeter of quartz made by an electric fusion method.

When compared to the case where the quartz is formed by the flame fused method or the electric fusion method, the focus ring 151 made by a plasma fusion method according to the present embodiment may have a low hydroxide concentration and a low bubble density. In exemplary embodiments, the focus ring 151 made by a plasma fusion method may have a hydroxide concentration lower than about 50 ppm and a bubble density lower than 2 ea/cm³. For example, the focus ring 151 may have a hydroxide concentration of about 30 ppm and a bubble density of 1 ea/cm³ or lower. For example, forming a focus ring 151 with quartz made by a plasma fusion method may increase the lifetime of the focus ring 151, may suppress producing particles during a plasma process, and may reduce the number of particles in the chamber 100.

The cover ring 153 may be formed of or include the same quartz as that of the focus ring 151. For example, the cover ring 153 may be formed with a quartz made by a plasma fusion method. The cover ring 153 may have a hydroxide concentration of about 30 ppm and a bubble density of about 1 ea/cm³ or lower. In certain embodiments, the ground ring 154 may be formed with a quartz made by a plasma fusion method.

Referring back to FIG. 1, the window 160 may be provided between the lower housing 110 and the upper housing 120. The window 160 may be provided on the wall liner 140. The plasma 500 may be produced between the window 160 and the lower housing 110. For example, the plasma 500 may be formed below the window 160 and above the electrostatic chuck 130, the ring member 150 and/or the wafer W. The first and second RF powers 510 and 520 may be transmitted to the substrate W through the window 160. In exemplary embodiments, the window 160 may be formed of or include a dielectric material. For example, the window 160 may include quartz. For example, when the window 160 includes quartz, the quartz may be made by a plasma fusion method, a flame fusion method, or an electric fusion method. For example, the window 160 may include a synthetic quartz. Alternatively, the window 160 may include natural quartz. When the window 160 is formed of a dielectric material, it may reduce transmission loss of the first and second RF powers 510 and 520.

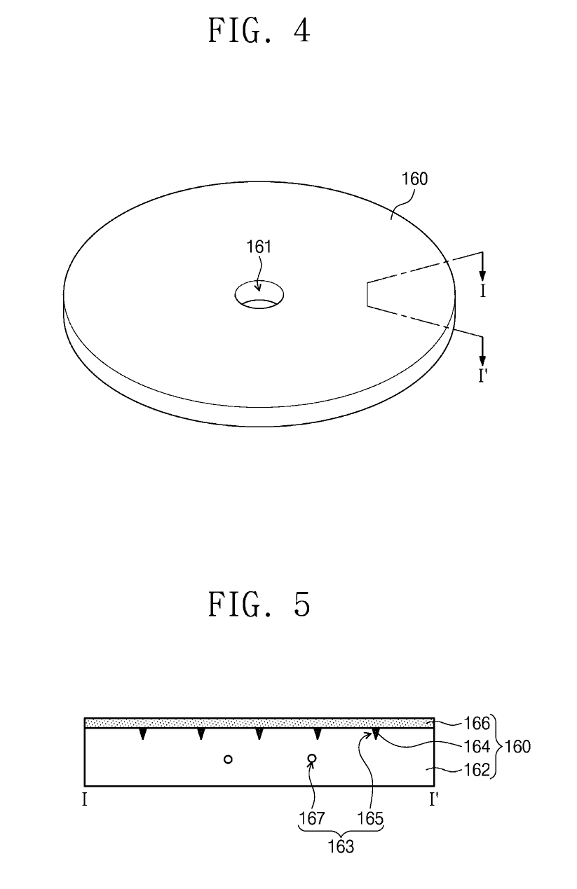

FIG. 4 illustrates an example of the window 160 of FIG. 1. FIG. 5 is a cross-sectional view taken along line I-I′ of FIG. 4.

Referring to FIGS. 4 and 5, the window 160 may include a disk 162, fillers 164, and a passivation layer 166.

The disk 162 may be formed of or include a dielectric material, and may be referred to as a dielectric disk. For example, the disk 162 may be formed of or include a ceramic material containing aluminum oxide (Al₂O₃). The disk 162 may have a gas hole 161 and voids 163. In certain embodiments, the disk 162 may be made of quartz. For example, when the disk 162 is made of quartz, the quartz may be made by a plasma fusion method, a flame fusion method, or an electric fusion method. For example, the disk 162 may be made of a synthetic quartz. Alternatively, the disk 162 may be made of natural quartz.

The gas hole 161 may be formed to pass through the center of the disk 162. The gas hole 161 may be connected to the gas supply unit 200. The gas supplied from the gas supply unit 200 may be provided on the substrate W through the gas hole 161.

The voids 163 may be formed in the disk 162. In exemplary embodiments, the voids 163 may include voids formed on a top surface of the disk 162. The voids 163 may have various sizes, ranging from about 1 mm to about 1 nm. In exemplary embodiments, the voids 163 may include top voids 165 and lower voids 167. The top voids 165 may be formed on the top surface of the disk 162. For example, the top voids 165 may be grooves and/or pits, which are unevenly formed on the top surface of the disk 162. The lower voids 167 may be formed in the disk 162. In the disk 162, the lower voids 167 may act as defects. Hereinafter, the top voids 165 will be described in more detail.

The fillers 164 may be provided in the top voids 165 and on the top surface of the disk 162. The fillers 164 may be provided to fill the top voids 165, and thus, the disk 162 provided with the fillers 164 may have a flat top surface. For example, the fillers 164 may flatten the top surface of the disk 162. In some embodiments, the top surface of the disk 162 may face downward in the chamber 100 of the plasma system 10 of FIG. 1. For example, the top surface of the disk may face plasma 500 in the chamber 100 of the plasma system 10 of FIG. 1.

In exemplary embodiments, the fillers 164 may be formed of or include a dielectric material, and may be referred to as a dielectric layer, or a first dielectric layer. Fillers 164 may also be referred to as insulating fillers, or an insulating filler layer. When the fillers 164 are formed of the dielectric material, transmission loss of the first and second RF powers 510 and 520 of FIG. 1 may be reduced. As an example, the fillers 164 may be formed of or include silicon oxide (SiO₂). As another example, the fillers 164 may be formed of or include silicon nitride (SiN). As other examples, the fillers 164 may be formed of or include metal oxides, such as yttrium oxide (Y₂O₃), aluminum oxide (Al₂O₃), zirconium oxide (ZrO₂), magnesium oxide (MgO), calcium oxide (CaO), or yttrium aluminum garnet (YAG; Y₃Al₅O₂).

In exemplary embodiments, the fillers 164 may be formed of or include a semiconductor layer. When the fillers 164 are formed of the semiconductor layer, transmission loss of the first and second RF powers 510 and 520 may be reduced. The fillers 164 may be formed of or include silicon.

In exemplary embodiments, the fillers 164 may be formed of or include a polymer layer. When the fillers 164 are formed of the polymer layer, transmission loss of the first and second RF powers 510 and 520 may be reduced. For example, the fillers 164 may be formed of or include thermosetting resins, such as phenolic resins or urea resins. In exemplary embodiments, the fillers 164 may be formed of or include Teflon, e.g., polytetrafluoroethylene.

The passivation layer 166 may be provided to cover the fillers 164 and the top surface of the disk 162. The passivation layer 166 may protect the fillers 164 and the disk 162 from the plasma 500. In exemplary embodiments, the passivation layer 166 may be formed of or include a dielectric material, and may be referred to as a dielectric layer, or second dielectric layer. Passivation layer 166 may also be referred to as an insulating layer, or second insulating layer.

When the passivation layer 166 is formed of the dielectric material, transmission loss of the first and second RF powers 510 and 520 may be reduced. For example, the passivation layer 166 may be formed of or include yttrium oxide (Y₂O₃).

On the fillers 164 and the disk 162, the passivation layer 166 may have a flat top surface. For example, if the fillers 164 are not formed, the passivation layer 166 may have a non-flat top surface or an uneven structure. The uneven structure may be easily damaged by the plasma 500 of FIG. 1. For example, the uneven structure may act as a particle source, under the plasma environment. For example, the fillers 164 may prevent or suppress the passivation layer 166 from having the uneven structure, which may reduce the number of particles produced by plasma. For example, the fillers 164 may help flatten the top surface of the passivation layer 166.

A method of fabricating the window 160 will be described below.

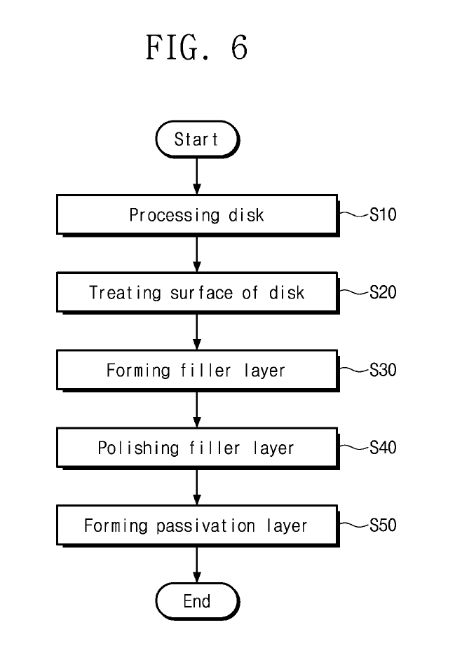

FIG. 6 is a flow chart illustrating a method of fabricating of the window 160.

Referring to FIG. 6, the fabrication method of the window 160 may include processing the disk 162 (in S10), texturing the disk 162 (in S20), forming a filler layer 168 (in S30), polishing the filler layer 168 (in S40), and forming the passivation layer 166 (in S50).

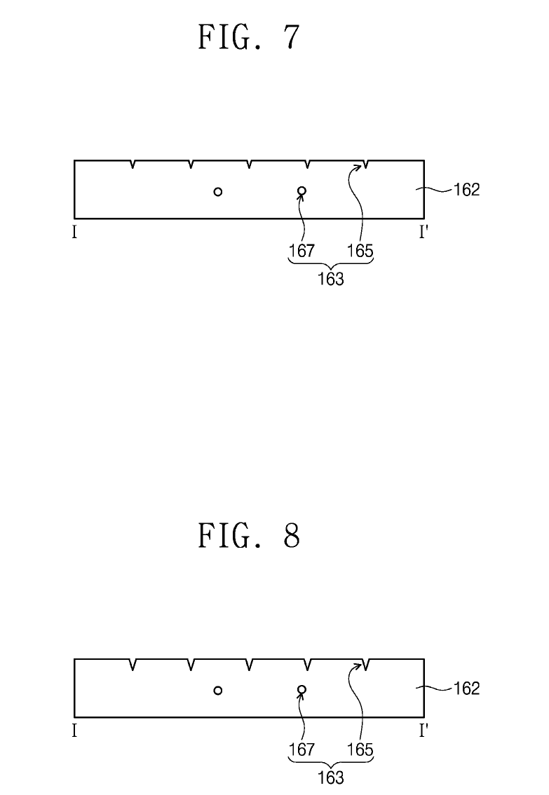

FIGS. 7 to 10 are cross-sectional views illustrating a method of fabricating the window 160, described with reference to FIG. 6.

Referring to FIGS. 6 and 7, the disk 162 is processed (in S10). In exemplary embodiments, the disk 162 may be fabricated through a high temperature process. For example, the disk 162 may include a ceramic material formed by a sintering method. The high temperature process may lead to formation of the voids 163 in the disk 162. For example, the high temperature of a manufacturing process of the disk 162 may cause the voids 163 to form within the disk 162 and/or on the surface of the disk 162. For example, the voids 163 may include the top voids 165 and the lower voids 167, which are formed by the high temperature process of forming the ceramic material.

Referring to FIGS. 6 and 8, a surface of the disk 162 is treated (in S20). In exemplary embodiments, the treating of the disk 162 (in S20) may include dipping the disk 162 in hydrofluoric acid solution. The treating of the disk 162 (in S20) may be performed to reduce sizes of the top voids 165. In exemplary embodiments, the sizes of the top voids 165 may be increased by the surface treatment or the surface texturing process. The top voids 165 may be formed by removing particles and/or impurities from the top surface of the disk 162.

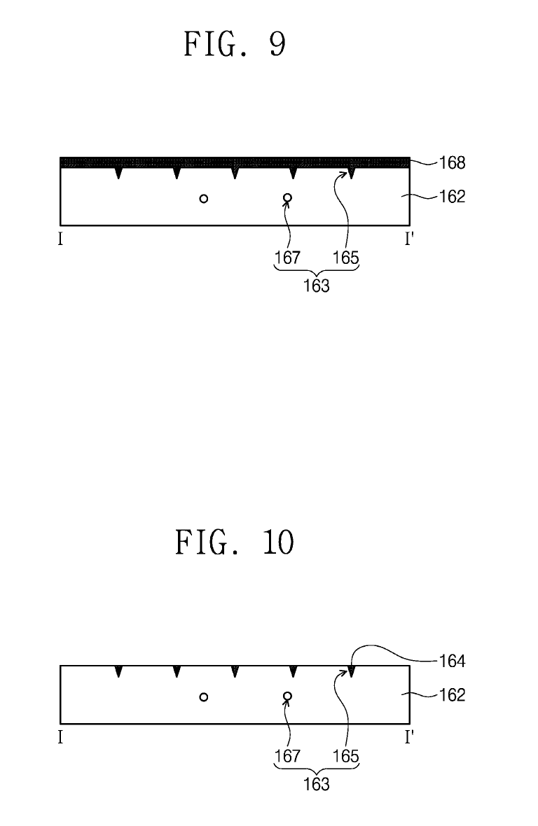

Referring to FIGS. 6 and 9, the filler layer 168 is formed on the disk 162 (in S30). For example, the filler layer 168 may be formed by a sol-gel method, a dropping method, a melting method, a deposition method, or an electroplating method. The filler layer 168 may be formed of or include a dielectric material or a metallic material. The filler layer 168 may be formed to fill the top voids 165. In the case where the filler layer 168 includes the metallic material, a thermal treatment process may be further performed on the filler layer 168. In this case, the filler layer 168 may be oxidized.

Referring to FIGS. 6 and 10, the filler layer 168 is polished to form the fillers 164 in the top voids 165 (in S40). For example, the polishing of the filler layer 168 may be performed using a chemical mechanical polishing (CMP) method. The top surface of the disk 162 may be partially exposed around the fillers 164. The top voids 165 may be filled with the fillers 164. The disk 162 with the fillers 164 may have a planarized top profile. In exemplary embodiments, the steps of forming and polishing the filler layer 168 (in S30 and S40) may be performed to form the fillers 164.

Referring to FIGS. 5 and 6, the passivation layer 166 is formed on the fillers 164 and the disk 162 (in S50). The passivation layer 166 may include, for example, yttrium oxide (Y₂O₃). The yttrium oxide of the passivation layer 166 may be formed by an aerosol method. For example, the passivation layer 166 may include a material different from the material included in the filler layer 168 and the filler 164. In certain embodiment, the passivation layer 166 may include the same material as the material included in the filler layer 168 and the filler 164.

Referring back to FIG. 1, the antenna guide 170 may be provided between the window 160 and the upper housing 120. The antenna guide 170 may be used to fasten first and second antennas 332 and 334 of the upper RF power supply unit 300 on the window 160. The antenna guide 170 may be disposed between the first and second antennas 332 and 334. For example, the antenna guide 170 may be formed of or include the same dielectric material as that of the window 160. The antenna guide 170 may be used to insulate the first and second antennas 332 and 334 from each other. In exemplary embodiments, the antenna guide 170 may be formed of or include a plastic material. For example, the antenna guide 170 may be disposed between the window 160 and the respective first and second antennas 332 and 334.

The gas supply unit 200 may be configured to supply gas (not shown) into the chamber 100 or between the lower housing 110 and the window 160. In exemplary embodiments, the gas supply unit 200 may include a storage tank 210 and a mass flow controller 220. The storage tank 210 may be configured to store gas. The gas may include purge gas, etching gas, deposition gas, or reaction gas. For example, the gas may include nitrogen (N₂) gas, hydrogen (H₂) gas, oxygen (O₂) gas, hydrofluoric acid (HF) gas, chlorine (Cl₂) gas, sulfur hexafluoride (SF₆) gas, methyl (CH₃) gas, or silane (SiH₄) gas. The mass flow controller 220 may be provided between the storage tank 210 and the chamber 100 to connect them to each other. The mass flow controller 220 may be configured to control a flow amount of gas.

The upper RF power supply unit 300 may include first and second RF power sources 312 and 314, first and second matchers 322 and 324, first and second antennas 332 and 334, first and second inductors 342 and 344, and first and second capacitors 352 and 354.

The first and second RF power sources 312 and 314 may be configured to produce the first and second RF powers 510 and 520, respectively. The first and second RF powers 510 and 520 may be provided to the first and second antennas 332 and 334, respectively. The first and second RF powers 510 and 520 may be independently controlled.

The first and second matchers 322 and 324 may be connected to the first and second RF power sources 312 and 314, respectively. Each of the first and second matchers 322 and 324 may be configured to control impedance of a corresponding one of the first and second RF powers 510 and 520.

The first and second antennas 332 and 334 may be provided between the window 160 and the upper housing 120. In exemplary embodiments, the first antenna 332 may be provided above a center region of the substrate W. The second antenna 334 may be provided above an edge region the substrate W. The first and second antennas 332 and 334 may be used to transmit the first and second RF powers 510 and 520 to the gas on and/or over the substrate W.

The first and second antennas 332 and 334 may be provided to be spaced apart from, but adjacent to, each other. For example, the first and second antennas 332 and 334 may be disposed close to each other and may not contact each other. In exemplary embodiments, the first and second antennas 332 and 334 may be electromagnetically coupled to each other within a small distance. For example, the first and second antennas 332 and 334 may be configured to have first mutual inductance M1. In exemplary embodiments, the first and second antennas 332 and 334 may be configured to have the same winding direction. For example, the first and second antennas 332 and 334 may be loop antennas or helical antennas having respective coil windings, and the winding direction of the coil of the first antenna 332 may be the same as the winding direction or the coil of the second antenna 334.

The first and second inductors 342 and 344 may connect the first and second antennas 332 and 334 to the first and second matchers 322 and 324, respectively. The first and second inductors 342 and 344 may be electromagnetically coupled to each other within a small distance. The first and second inductors 342 and 344 may be configured to have second mutual inductance M2 offsetting the first mutual inductance M1. For example, the first and second mutual inductances M1 and M2 may have the same absolute value but opposite signs. The first mutual inductance M1 may cause interference between the first and second RF powers 510 and 520, but in the case where the first and second mutual inductances M1 and M2 are offset, the interference between the first and second RF powers 510 and 520 may be prevented, removed, or minimized. Accordingly, the impedance of the first and second RF powers 510 and 520 may be stably controlled by the first and second matchers 322 and 324.

The winding and/or coupling directions of the first and second inductors 342 and 344 may be different from those of the first and second antennas 332 and 334. For example, the first and second inductors 342 and 344 may have helical or spiral structures. The points next to respective first and second inductors 342 and 344 of FIG. 1 depict the winding directions of the first and second inductors 342 and 344. In exemplary embodiments, the first and second inductors 342 and 344 may be configured to have different winding directions. In exemplary embodiments, the first and second inductors 342 and 344 may be configured to have the same winding number. The winding numbers of the first and second inductors 342 and 344 may be the same as that of the first and second antennas 332 and 334. For example, the winding number of each of the first and second inductors 342 and 344 may be about four.

The first and second capacitors 352 and 354 may be provided between and connected to the first and second antennas 332 and 334 and the ground. The first and second capacitors 352 and 354 may be used to control impedance of the first and second RF powers 510 and 520 at the first and second antennas 332 and 334. In exemplary embodiments, the first and second capacitors 352 and 354 may be used to remove noise from the first and second RF powers 510 and 520. In exemplary embodiments, each of the first and second capacitors 352 and 354 may have capacitance of about 50 pF to 2000 pF. In exemplary embodiments, the first and second capacitors 352 and 354 may be used to control ignition of the plasma 500.

The lower RF power supply unit 400 may include a third RF power source 412 and a third matcher 414. The third RF power source 412 may be configured to produce the third RF power 530. The third matcher 414 may be configured to control impedance of the third RF power 530. The third RF power 530 may be lower than the first and second RF powers 510 and 520. For example, the third RF power 530 may range from about 100 W to about 1000 W.

According to exemplary embodiments of the inventive concept, a window may include fillers, which are provided to fill voids of a disk, and a passivation layer on the fillers and the disk. The fillers may prevent the passivation layer from having an uneven structure and consequently to suppress the occurrence of particles. In addition, a ring member of a plasma system may include an edge ring whose hydroxide concentration and bubble density are lower than those of the conventional one. Accordingly, lifetime of the edge ring can be increased.

Filling top voids 165 with fillers 164 and forming a passivation layer 166 on the disk 162 were described above with reference to FIGS. 5 through 10. The passivation layer 166 and the fillers 164 provide a protection structure for the disk 162 during a plasma process performed in the plasma system 10. According to certain embodiments of the present disclosure, similar structures to the fillers 164 and a passivation layer 166 may be provided on the ring member 150. For example, a filler 164 and a passivation layer 166 may be formed respectively in a top void and on a surface which faces plasma 500 in the chamber 100. For example, fillers 164 and passivation layers 166 may be formed respectively in voids and on surfaces of the focus ring 151, cover ring 153, and/or ground ring 154 similarly to the disk 162. For example, fillers 164 and passivation layers 166 may be formed on top surfaces of the focus ring 151 and the cover ring 153. In certain embodiments, fillers 164 and passivation layers 166 may be formed on side surfaces of the cover ring 153 and the ground ring 154 which may be exposed to plasma 500 in the chamber 100. The top voids of the ring member 150, focus ring 151, cover ring 153, and/or ground ring 154 may be pits or grooves formed on the respective surfaces as similarly described with respect to the disk 162 above.

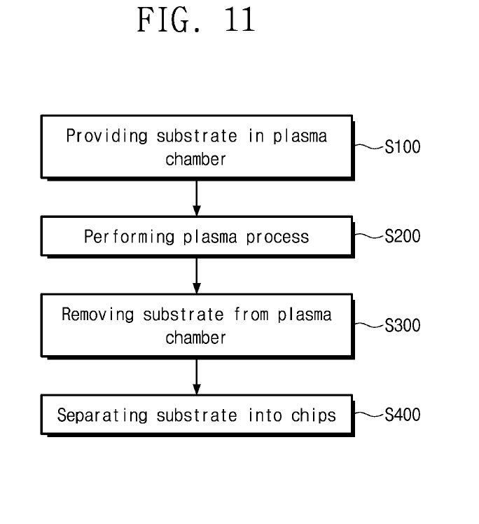

FIG. 11 is a flow chart illustrating a method of manufacturing a semiconductor device according to an exemplary embodiment of the present disclosure. Regarding to FIG. 11, the manufacturing method includes steps of providing a semiconductor substrate in a plasma chamber (S100), performing a plasma process on the semiconductor substrate (S200), removing the semiconductor substrate from the plasma chamber (S300), and separating the semiconductor substrate into a plurality of chips (S400). For example, the plasma process may include an etching process, an ashing process, a deposition process, a sputtering process and/or a cleaning process. For example, during the plasma process, a dielectric layer or a conductor layer may be etched. For example, the dielectric layer or the conductor layer may be patterned by the plasma while a mask layer covers a portion of the dielectric layer or the conductor layer. For example, the mask layer may be formed by a photolithography process, e.g., a double patterning process or a quadruple patterning process.

The plasma chamber may be a chamber 100 of a plasma system 10 described in the previous embodiments of the current disclosure. The plasma chamber may include various features described with reference to FIGS. 1 through 10. The semiconductor substrate may be a bare substrate on which a semiconductor circuit may be formed in later steps of processes. Alternatively, the semiconductor substrate may be a substrate on which a semiconductor circuit is already formed. After removing the semiconductor substrate from the chamber and/or performing additional processes completing semiconductor circuits on the semiconductor substrate, the semiconductor substrate may be divided into a plurality of semiconductor chips as shown in step S400 of FIG. 11. The semiconductor substrate may be the substrate W described with reference to FIG. 1. For example, the semiconductor chips may be packaged to form semiconductor devices.

While example embodiments of the inventive concepts have been particularly shown and described, it will be understood by one of ordinary skill in the art that variations in form and detail may be made therein without departing from the spirit and scope of the attached claims.

What is claimed is:

1. A dielectric window comprising:
a dielectric material disk with at least one void;
a filler filled in the void to allow the dielectric material disk to have a flat top surface; and
a passivation layer provided on the filler and the dielectric material disk.

2. The dielectric window of claim 1, wherein the filler comprises silicon oxide or silicon nitride.

3. The dielectric window of claim 1, wherein the filler comprises yttrium oxide, aluminum oxide, zirconium oxide, magnesium oxide, calcium oxide, or YAG.

4. The dielectric window of claim 1, wherein the filler comprises silicon.

5. The dielectric window of claim 1, wherein the filler comprises a thermosetting resin including a phenolic or urea resin.

6. A method comprising:
providing a substrate in a plasma chamber;
performing a plasma treatment on a surface of the substrate;
removing the substrate from the plasma chamber; and
separating the substrate into chips,
wherein the plasma chamber comprises a dielectric window,
wherein the substrate is disposed below the dielectric window while the plasma treatment is performed,
wherein plasma is formed between the dielectric window and the substrate, and
wherein the dielectric window comprises:
a dielectric disk;
a first insulating layer formed in a pit of a first surface of the dielectric disk; and
a second insulating layer formed on the first insulating layer and on the first surface of the dielectric disk.

7. The method of claim 6, wherein the first insulating layer comprises a first material different from a material comprising the second insulating layer.

8. The method of claim 6, wherein the first insulating layer comprises the same material as a material comprising the second insulating layer.

9. The method of claim 6, wherein the first surface of the dielectric disk faces the substrate when the plasma is formed.

10. The method of claim 6, wherein the dielectric disk comprises quartz.

11. A plasma system comprising:
a lower housing;
an electrostatic chuck provided in the lower housing and used to load the substrate thereon;
a ring member provided to enclose the electrostatic chuck and an edge of the substrate on the electrostatic chuck;
an upper housing provided over the ring member and the electrostatic chuck to cover the lower housing; and
a dielectric window provided between the upper housing and the lower housing,
wherein the dielectric window comprises:
a dielectric material disk with at least one void;
a filler provided to fill the at least one void and to planarize a first surface of the dielectric material disk; and
a passivation layer provided on the filler and the first surface of the dielectric material disk.

12. The plasma system of claim 11, wherein the ring member comprises:
a ground ring surrounding the electrostatic chuck; and
an edge ring provided on the ground ring to surround the edge of the substrate,
wherein the edge ring comprises quartz having a hydroxide concentration of 30 ppm or lower and a bubble density of 1 ea/cm³ or lower.

13. The plasma system of claim 12, wherein the quartz is natural quartz.

14. The plasma system of claim 12, wherein the quartz is formed by a plasma fusion method.

15. The plasma system of claim 11, further comprising:
an antenna guide provided between the dielectric window and the upper housing;
antennas provided on the antenna guide and configured to provide an RF power to a region on the substrate through the dielectric window;
RF sources configured to provide the RF powers to the antennas;
matchers provided between and connected to the antennas and the RF sources and used to control impedance of the RF powers; and
inductors provided between and connected to the matchers and the antennas and used to prevent interference between the RF powers,
wherein the inductors have different winding directions.

16. The plasma system of claim 11, wherein the first surface of the dielectric material disk faces downward toward the substrate during performing the plasma treatment on the surface of the substrate.

17. The plasma system of claim 16, wherein the ring member comprises:
a first dielectric layer formed in a pit of a top surface of the ring member; and
a second dielectric layer formed on the first dielectric layer and the top surface of the ring member.

18. The plasma system of claim 17, wherein the first and second dielectric layers are formed of different materials from each other.

19. The plasma system of claim 11, wherein the chips are semiconductor chips including semiconductor circuits.

20. The plasma system of claim 19, wherein the plasma treatment is an etching process.
